(19) United States
(12) Patent Application Publication
(10) Pub. No.: US 2016/0111597 A1
(43) Pub. Date: Apr. 21, 2016

(54) GRAPHICAL MICROSTRUCTURE OF LIGHT EMITTING DIODE SUBSTRATE

(71) Applicant: Genesis Photonics Inc., Tainan City (TW)

(72) Inventor: Cheng-Pin Chen, Tainan City (TW)

(21) Appl. No.: 14/886,097

(22) Filed: Oct. 19, 2015

(30) Foreign Application Priority Data
Oct. 17, 2014 (TW) 103135960

(51) Int. Cl. H01L 33/20; H01L 33/42; H01L 33/32

(52) U.S. Cl. CPC H01L 33/20; H01L 33/32; H01L 33/42

(57) ABSTRACT

The invention relates to a patterned microstructure of a light emitting diode (LED) substrate. The substrate is provided with patterned microstructures arranged in an array. Each patterned microstructure includes a bottom surface and a lateral surface adjacent to the bottom surface. There is an angle θ between the lateral surface and the bottom surface, where 0°<θ<90°. The length of the bottom surface ranges between 2.5 microns and 2.8 microns. An end of the lateral surface far away from the bottom surface is gradually shrunk into an intersection, and the height between the intersection and the bottom surface ranges between 1.5 microns and 1.9 microns. Accordingly, the invention can effectively achieve improving light extraction efficiency of the LED by optimizing the size of the patterned microstructure cyclically and alternately arranged on the LED substrate.

### CROSS-REFERENCE TO RELATED APPLICATION

This application claims the priority benefit of Taiwan application serial no. 103135960, filed on Oct. 17, 2014. The entirety of the above-mentioned patent application is hereby incorporated by reference herein and made a part of this specification.

### BACKGROUND

1. Field of the Invention

The invention is directed to a patterned microstructure of an LED substrate and more particularly, to a patterned microstructure formed on an LED substrate, which can achieve effectively improving light extraction efficiency of the LED by optimizing the size of the patterned microstructure cyclically and alternately arranged on the LED substrate.

2. Description of Related Art

A light emitting diode (LED) in comparison with a conventional incandescent light source has advantages, such as being power-saving, small-volume, driven by a low voltage, mercury-free, no thermal radiation, fast operation response speed and a long lifespan. The LED has become an optimal light source for the next generation of energy-efficient lighting and thus, been widely applied in the lighting field, such as houseware indicators, LCD backlight sources, graphic display screens or automobile third brake lights. Semiconductor light emitting devices, including a resonant-cavity light emitting diode (RCLED), a vertical-cavity surface-emitting diode (VCSED) and an edge emitting laser are all currently available effective light-emitting devices.

In a conventional LED employing group III nitride as an epitaxial structure, for example, an n-type semiconductor layer, a light-emitting structure layer and a p-type semiconductor layer are stacked in order on a substrate, where in order to enhance a current spreading effect and light extraction efficiency, a transparent conductive layer (e.g., Indium tin oxide (ITO)) is commonly disposed on the p-type semiconductor layer; and then a p-type electrode and an n-type electrode are disposed respectively on the p-type semiconductor layer and the n-type semiconductor layer. The p-type electrode and the n-type electrode are disposed respectively on the p-type semiconductor layer and the n-type semiconductor layer in an ohmic contact manner. In an optimal LED, as carriers are combined into photos in the light-emitting structure layer, the LED will have light-emitting efficiency of 100% if all the photos can radiate to the outside. However, in actual implementation, the photos generated by the light-emitting structure layer may not be propagated to the outside in the 100% light-emitting efficiency due to a variety of loss mechanisms. For example, a misfit dislocation defeat may occur to the LED due to the stress resulted from the lattice mismatch between the substrate and an epitaxial film, and part of the misfit dislocation defeat may even extend to a crystalline surface, which is referred to as a threading dislocation defect. For example, a lattice mismatch amount between a sapphire substrate and a GaN thin film may be approximately 16%, which easily leads the GaN thin film grown on the Al₂O₃ substrate to have a high density of defects, and as a result, the light-emitting structure layer has poor crystalline quality, and internal quantum efficiency of the LED is reduced, such that light-emitting illuminance of the LED is reduced, and heat is generated, which causes affection to the light-emitting efficiency. In order to effectively improve the light-emitting efficiency of the LED, an application for the invention, entitled “PATTERNED BASE MATERIAL AND LIGHT EMITTING DIODE COMPONENT FOR LIGHTEMITTING ANGLE OF CONVERGENCE” was filed by one of the named inventors of the invention on Apr. 24, 2012 in Taiwan, and was then published as Taiwan patent application publication No. 201345003, which discloses changing a travelling direction of light and converging the light emitting angle of the light emitting diode element by a plurality of stripe-shaped parts on a substrate surface, so as to increase light directivity and illuminant efficiency and facilitates in improving the misfit dislocation defeat occurring due to the lattice mismatch between the substrate and the epitaxial film by employing the plurality of stripe-shaped parts on the substrate surface in the related art, guiding the light laterally transmitted between the n-type semiconductor layer and the p-type semiconductor layer as forward light to forward emit out of the LED device, and converging the light emitting angle to 100° to 110°, such that the light emitting efficiency can be improved since the light directivity is improved, and the light emitting out can be prevented from being absorbed by other adjacent LED devices. However, per experiments and researches for several times by the inventor, the size and the formed structure of graphic structures formed by the plurality of strip parts on the substrate have not achieved optimization of the light-emitting efficiency, and therefore, the inventor considers that the light-emitting efficiency of the LED needs further adjustment and improvement.

### SUMMARY

In light of the foregoing, the application entitled “PATTERNED BASE MATERIAL AND LIGHT EMITTING DIODE COMPONENT FOR LIGHTEMITTING ANGLE OF CONVERGENCE” has defects, such as inapparently improved light-emitting efficiency of the LED due to the patterned structures and the size thereof on the substrate not being optimized, the inventor has been diligently dedicates in how to improve the defects in accordance with his wealth of professional knowledge and long-term practical experience, and thus, proposes the invention.

A main object of the invention lines in providing a patterned microstructure of a light emitting diode (LED) substrate and especially a patterned microstructure formed on the LED substrate, which can effectively achieve improving light extraction efficiency of the LED by optimizing sizes of the patterned microstructures arranged cyclically and alternately on the LED substrate.

In order to achieve the objects of the invention, a patterned microstructure of an LED substrate is provided. The substrate has a plurality of patterned microstructures arranged in an array, and each patterned microstructure includes a bottom surface and a lateral surface adjacent to the bottom surface, and an angle θ is included between the lateral surface and the bottom surface, wherein 0°<θ<90°. A length of the bottom surface ranges between 2.5 microns and 2.8 microns, an end of the lateral surface which is far away from the bottom surface shrunk into an intersection, and a height between the intersection and the bottom surface ranges between 1.5 microns and 1.9 microns.

In the patterned microstructure of the LED substrate as described above, the patterned microstructure are cyclically arranged, and a distance between each two of the patterned microstructure on the same row is the same.

In the patterned microstructure of the LED substrate as described above, the patterned microstructure are alternately arranged.

In the patterned microstructure of the LED substrate as described above, the distance ranges between 0.2 microns and 0.5 microns.

In the patterned microstructure of the LED substrate as described above, the bottom surface is presented in a circular shape, a triangular shape, a rectangular shape or a hexagonal shape.

In the patterned microstructure of the LED substrate as described above, an aspect of the patterned microstructures is a cone structure or a pyramid structure.

In the patterned microstructure of the LED substrate as described above, the patterned microstructures are formed on the substrate by an integration molding process, a molding process or an imprinting process.

In the patterned microstructure of the LED substrate as described above, a material of the substrate is selected from a group consisting of sapphire (Al₂O₃), silicon carbide (SiC), silicon (Si), gallium arsenide (GaAs), zinc oxide (ZnO) and a hexagonal crystalline material.

In the patterned microstructure of the LED substrate as described above, a material of the substrate is selected from a group consisting of sapphire (Al₂O₃), silicon carbide (SiC), silicon (Si), gallium arsenide (GaAs), zinc oxide (ZnO) and a hexagonal crystalline material.

In order to achieve another object of the invention, an LED device is provided. The LED device at least includes the substrate having the patterned microstructure as described above, an epitaxial layer formed of a group III nitride semiconductor material by an epitaxy process on the patterned microstructure and two electrodes operating collaboratively to provide electricity. The epitaxial layer has an n-type semiconductor layer formed on the substrate having the patterned microstructure, an active light-emitting layer formed on the n-type semiconductor layer and a p-type semiconductor layer formed on the active light-emitting layer. The two electrodes includes a p-type electrode formed on the p-type semiconductor layer in an ohmic contact manner and an n-type electrode formed on the n-type semiconductor layer in the ohmic contact manner, respectively, and a transparent conductive layer is formed between the p-type semiconductor layer and the p-type electrode.

Thereby, the patterned microstructure of the LED substrate of the invention, in which a plurality of microstructures presented in the cone shape is formed on the surface of the LED substrate, can facilitate in reducing a total reflection angle of the light emitted by the active light-emitting layer of the subsequently manufactured LED device by means of non-planarity of the substrate surface, such that the light emitted by the active light-emitting layer of the LED device when contacting the patterned microstructures and the substrate can contribute to effectively improving light extraction efficiency of the LED by means of being refracted and reflected for twice. In addition, the patterned microstructures of the LED substrate of the invention can improve the light extraction efficiency of the LED device for more than 3% in comparison with the performance of an LED substrate in the application for prior invention, entitled “PATTERNED BASE MATERIAL AND LIGHT EMITTING DIODE COMPONENT FOR LIGHTEMITTING ANGLE OF CONVERGENCE” previously filed by one of the named inventors of the invention by optimizing the size and arrangement of the patterned microstructures arranged cyclically and alternately on the LED substrate.

### BRIEF DESCRIPTION OF THE DRAWINGS

FIG. 1: a schematic cross-sectional diagram illustrating a patterned microstructure of a light emitting diode (LED) substrate in accordance with a preferred embodiment of the invention.

FIG. 2: a top-view diagram illustrating the patterned microstructure of the LED substrate in accordance with a preferred embodiment of the invention.

FIG. 3: a schematic cross-sectional diagram illustrating a single patterned microstructure of the patterned microstructure of the LED substrate in accordance with a preferred embodiment of the invention.

FIG. 4: a schematic cross-sectional diagram illustrating an LED device including the patterned microstructure of the LED substrate in accordance with a preferred embodiment of the invention.

### DESCRIPTION OF EMBODIMENTS

The objects and advantages in structural design and functions of the invention will be described according to the preferred embodiments of the invention with reference to the accompanying drawings, such that the invention can be clear and comprehensive to the Examiner.

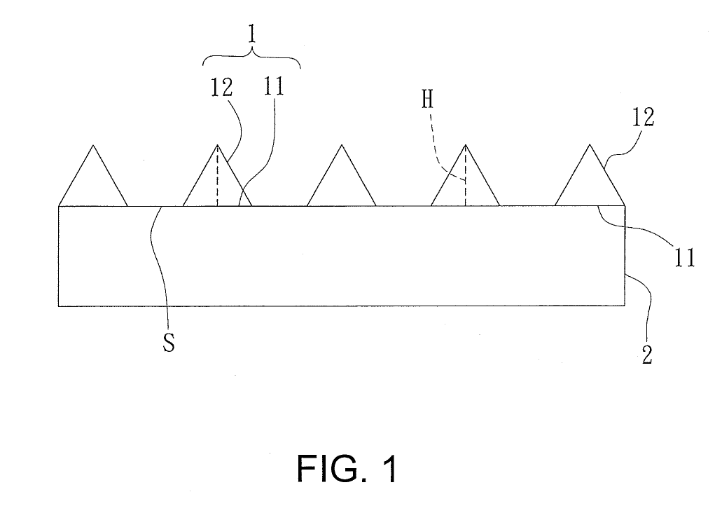

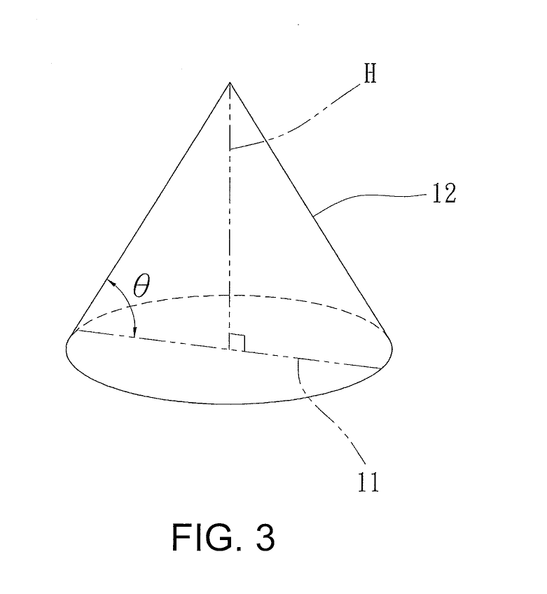

First, referring to FIG. 1 through FIG. 3, a schematic cross-sectional diagram illustrating a patterned microstructure of a light emitting diode (LED) substrate, a top-view diagram illustrating the patterned microstructure of the LED substrate and a schematic cross-sectional diagram illustrating a single patterned microstructure in accordance with a preferred embodiment of the invention. A substrate (2) of the patterned microstructure of the LED substrate of the invention includes a plurality of patterned microstructures (1) arranged in an array. Each of the patterned microstructures (1) includes a bottom surface (11) and a lateral surface (12). The lateral surface (12) is adjacent to the bottom surface (11), and an angle θ is included between the lateral surface (12) and the bottom surface (11), where 0°<θ<90°. A length of the bottom surface (11) ranges between 2.5 microns and 2.8 microns. An end of the lateral surface (12) which is far away from the bottom surface (11) is gradually shrunk into an intersection (13), and a height (H) between the intersection (13) and the bottom surface (11) ranges between 1.5 microns and 1.9 microns.

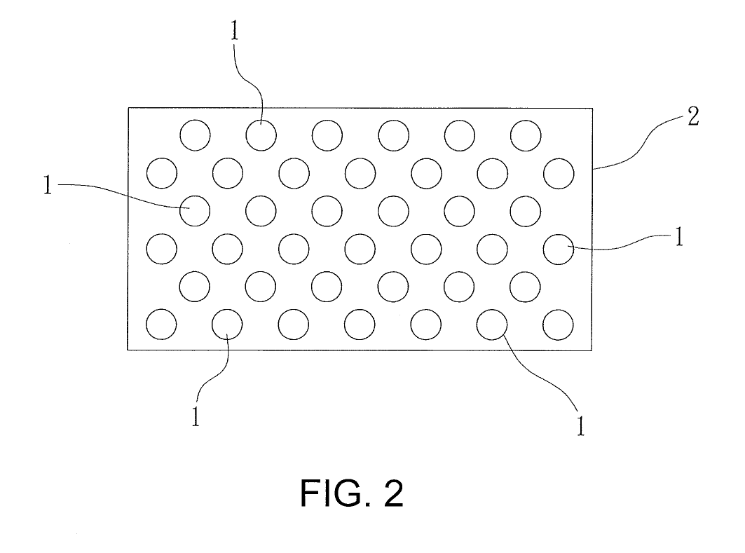

Additionally, referring to FIG. 2 again, the patterned microstructures (1) are cyclically arranged, and each two patterned microstructures (1) are spaced in the same distance (S), and the distance (S) ranges between 0.2 microns and 0.5 microns. Moreover, the patterned microstructures (1) are alternately arranged on a surface of the substrate (2).

In addition, the bottom surface (11) of each of the patterned microstructures (1) is presented in an aspect of a circular shape, a triangular shape, a rectangular (e.g., Square, rhombus, and parallelogram) shape or a hexagonal shape, and each of the patterned microstructures (1) is an aspect of a cone structure or a pyramid structure. In a preferred embodiment of the invention, the patterned microstructure (1) is presented in an aspect that each bottom surface (11) is circular, and the entire is a cone structure.

Additionally, the patterned microstructures (1) of the invention are formed on the substrate (2) by one of an integration molding process, a molding process and an imprinting process. The substrate (2) is made of a material selected from a group consisting of sapphire (Al₂O₃), silicon carbide (SiC), silicon (Si), gallium arsenide (GaAs), zinc oxide (ZnO) and a hexagonal crystalline material, while the patterned microstructures (1), in the same way as the substrate (2), are also made of a material selected from a group consisting of sapphire (Al₂O₃), silicon carbide (SiC), silicon (Si), gallium arsenide (GaAs), zinc oxide (ZnO) and the hexagonal crystalline material. In a preferred embodiment of the invention, the patterned microstructures (1) are formed on the substrate (2) by an integration molding process. Therefore, the patterned microstructures (1) and the substrate (2) are preferably made of a sapphire material, and the patterned microstructures (1) may be formed as a plurality of microstructures on the substrate (2) through a lithography process and an etching process, such as a dry or wet etching process. The processes and methods are well known to persons skilled in the art and are not the points that the invention intends to focus, and thus, will not be further described in the invention.

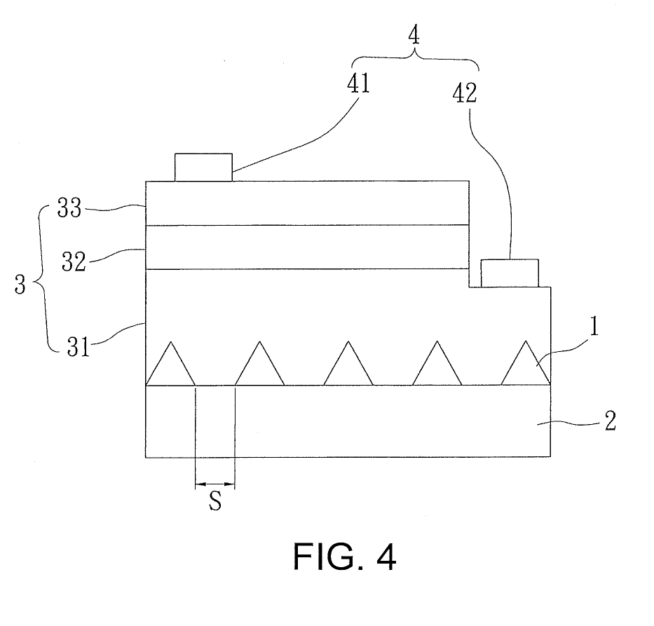

Furthermore, the patterned microstructure of the LED substrate described above may be applied in an LED device, referring to FIG. 4, FIG. 4 is a schematic cross-sectional diagram illustrating an LED device including the patterned microstructure of the LED substrate in accordance with a preferred embodiment of the invention. The LED device at least includes the substrate (2) having the patterned microstructures (1), an epitaxial layer (3) formed of a group III nitride semiconductor material by an epitaxy process on the patterned microstructures (1) and two electrodes (4) operating collaboratively to provide electricity. The epitaxial layer (3) has an n-type semiconductor layer (31) formed on the substrate (2) having the patterned microstructures (1), an active light-emitting layer (32) formed on the n-type semiconductor layer (31) and a p-type semiconductor layer (33) formed on the active light-emitting layer (32). The two electrodes (4) respectively includes a p-type electrode (41) formed on the p-type semiconductor layer (33) in an ohmic contact manner and an n-type electrode (42) formed on the n-type semiconductor layer (31) in the ohmic contact manner.

In addition, the group III nitride for forming the epitaxial layer (3) may one of or a combination of two or more of AlN, GaN, InN, AlGaN, AlInN, InGaN or AlInGaN.

Furthermore, in order to enhance the current spreading effect and the light extraction efficiency of the LED device, a transparent conductive layer (which is not illustrated) may be further formed between the p-type semiconductor layer (33) and the p-type electrode (41). A material of the transparent conductive layer may be selected from a group consisting of indium tin oxide (ITO), aluminum doped zinc oxide (AZO) or indium zinc oxide (IZO).

Based on the embodiments described above, the patterned microstructure of the LED substrate of the invention in comparison with the currently related art has the following advantages:

1. The patterned microstructure of the LED substrate of the invention, in which a plurality of microstructures presented in the cone shape is formed on a surface of the LED substrate, can facilitate in reducing a full reflection angle of the light emitted by the active light-emitting layer of the subsequently manufactured LED device by means of non-planarity of the substrate surface, such that the light emitted by the active light-emitting layer of the LED device when contacting the patterned microstructures and the substrate can contribute to effectively improving light extraction efficiency of the LED by means of being refracted and reflected for twice.

2. The patterned microstructure of the LED substrate of the invention can improve the light extraction efficiency of the LED device for more than 3% in comparison with the performance of the application entitled “PATTERNED BASE MATERIAL AND LIGHT EMITTING DIODE COMPONENT FOR LIGHTEMITTING ANGLE OF CONVERGENCE” previously filed by one of the named inventors of the invention by optimizing the size and arrangement of the patterned microstructures arranged cyclically and alternately on the LED substrate.

In light of the foregoing, the patterned microstructure of the LED substrate of the invention can truly achieve the expected effects of use based on the teaching of the embodiments described above. Meanwhile, the disclosure of the invention is not disclosed by any publication before the filing of the application of the invention and thus, complies with the provisions and requirements of the patent law. Accordingly, a patent application for the invention is to be filed and hereby requests for patent grant upon the examination.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

1. A patterned microstructure of a light emitting diode (LED) substrate, the substrate having a plurality of patterned microstructures arranged in an array, each of the patterned microstructures comprising a bottom surface and a lateral surface adjacent to the bottom surface, and an angle θ being included between the lateral surface and the bottom surface, wherein 0°<θ<90°, a length of the bottom surface ranges between 2.5 microns and 2.8 microns, an end of the lateral surface which is far away from the bottom surface is gradually shrunk into an intersection, a height between the intersection and the bottom surface ranges between 1.5 microns and 1.9 microns.

2. The patterned microstructure of the LED substrate according to claim 1, wherein the patterned microstructures are cyclically arranged, and a distance between each two of the patterned microstructure on the same row is the same.

3. The patterned microstructure of the LED substrate according to claim 2, wherein the patterned microstructure are alternately arranged.

4. The patterned microstructure of the LED substrate according to claim 2, wherein the distance ranges between 0.2 microns and 0.5 microns.

5. The patterned microstructure of the LED substrate according to claim 1, wherein the bottom surface is presented in a circular shape, a triangular shape, a rectangular shape or a hexagonal shape.

6. The patterned microstructure of the LED substrate according to claim 5, wherein a shape of the patterned microstructures is a cone structure or a pyramid structure.

7. The patterned microstructure of the LED substrate according to claim 3, wherein the patterned microstructures are formed on the substrate by an integration molding process, a molding process or an imprinting process.

8. The patterned microstructure of the LED substrate according to claim 1, wherein a material of the substrate is selected from a group consisting of sapphire (Al₂O₃), silicon carbide (SiC), silicon (Si), gallium arsenide (GaAs), zinc oxide (ZnO) and a hexagonal crystalline material.

9. The patterned microstructure of the LED substrate according to claim 1, where the patterned microstructure is made of a material selected from a group consisting of sapphire, silicon carbide (SiC), silicon (Si), gallium arsenide (GaAs), zinc oxide (ZnO) and a hexagonal crystalline material.

10. An LED device, at least comprising:
a substrate, wherein the patterned microstructure as recited in claim 1 is formed on the substrate;
an epitaxial layer, formed of a group III nitride semiconductor material by an epitaxy process on the patterned microstructure, wherein the epitaxial layer has an n-type semiconductor layer formed on the substrate having the patterned microstructure, an active light-emitting layer formed on the n-type semiconductor layer and a p-type semiconductor layer formed on the active light-emitting layer; and
two electrodes, operating collaboratively to provide electricity, wherein the two electrodes comprises a p-type electrode formed on the p-type semiconductor layer in an ohmic contact manner and an n-type electrode formed on the n-type semiconductor layer in the ohmic contact manner, respectively, and a transparent conductive layer is formed between the p-type semiconductor layer and the p-type electrode.
